(19) United States
(12) Patent Application Publication
(10) Pub. No.: US 2026/0099175 A1
(43) Pub. Date: Apr. 9, 2026

(54) FLEXIBLE DISPLAY COVER SUBSTRATE

(71) Applicant: Microcosm Technology (suzhou) Co., Ltd., Suzhou, Jiangsu (CN)

(72) Inventors: Chun-Yao OU, Suzhou, Jiangsu (CN); Yuan-Chieh WU, Suzhou, Jiangsu (CN); Tang-Chieh Huang, Suzhou, Jiangsu (CN)

(21) Appl. No.: 19/112,939

(22) PCT Filed: Jan. 12, 2023
(86) PCT No.: PCT/CN2023/071968

§ 371 Date: Mar. 18, 2025

(51) Int. Cl. G06F 1/16; B32B 7/12; B32B 17/10

(52) U.S. Cl. CPC G06F 1/1656; B32B 7/12; B32B 17/10366; G06F 1/1652; B32B 2255/10; B32B 2255/26; B32B 2457/20

(57) ABSTRACT

The present invention provides a flexible display cover comprising: an ultra-thin glass; a plastic film disposed on the ultra-thin glass; an anti-fouling layer disposed on the plastic film; an impact-resistant layer disposed on at least one surface of the ultra-thin glass or the plastic film, the impact-resistant layer comprising a disperse phase and a continuous phase, the disperse phase accounting for 10-50 wt % of the impact-resistant layer, an elastic modulus ratio of the disperse phase to the continuous phase being greater than or equal to 70, and the impact-resistant layer having an elastic modulus greater than or equal to 1 GPa; and an adhesive layer disposed between the ultra-thin glass and the plastic film, and the adhesive layer having an elastic modulus greater than or equal to 0.1 GPa. The flexible display cover has good bending resistance and impact resistance.

### BACKGROUND OF THE INVENTION

### Field of the Invention

The present invention relates to a flexible display cover substrate and, more particularly, to a flexible display cover substrate having the characteristics of scratch resistance, bending resistance and impact resistance at the same time.

### Description of the Prior Art

Flexible display devices have bending and folding properties and can be folded or rolled up. Therefore, they can be applied to a variety of fields, such as mobile phones, portable multimedia players (PMP), navigation devices, ultra-mobile computers (UMPC), e-books, e-paper and other related devices, and can also be applied to televisions, monitors and similar products. Since the flexible display device has a large amount of flexible polymer materials in its stacked layers, its strength is far less than that of the rigid display device containing the inorganic substrate, resulting in weak impact resistance of the flexible display device. During daily use by users, some minor collisions may cause the internal fragmentation of the flexible display device, or even damage the internal display components, resulting in abnormal display, such as black spots, broken bright spots and other display defects.

In actual application scenarios, the impact on the flexible display device is transient impact, and transient stress will be generated inside the display device. The transient impact mechanical scenario can be analyzed by the stress wave theory in dynamic mechanics. For general materials, it is usually unable to take both rigidity and damping properties into consideration at the same time. Although rigid materials can provide protection, they usually lack the damping property to absorb energy. In view of the importance of increasing the impact resistance of the display, the alternating lamination of two film materials (a rigid support material with transparency and a highly damping material with transparency and energy absorption) serving as a protection for the display when being impacted has been widely discussed and applied. As far as mobile device products are concerned, the folding screen is essentially a device with a larger screen that can be put into a pocket to improve portability. Therefore, under the requirement of thinness, the number of lamination layers and the thickness of a single layer of the impact-resistant cover substrate will be limited.

Devices using traditional glass cover substrates can have good impact resistance, which mainly benefits from the traditional glass cover substrate's ability to effectively absorb or disperse impact force, thereby protecting the display elements and touch electrodes below. In folding screens, because traditional glass cover substrates cannot be used, the flexible cover substrate of the folding screen is more likely to have surface dents or other damage under external force impact, making it difficult to effectively protect the display elements and touch electrodes below. If a thicker or double-layer flexible cover substrate solution is utilized, the impact resistance of the folding screen can be improved, but compared with the traditional glass cover substrate, there is still a large performance gap, and the thicker stacking structure will affect the bending characteristics and surface flatness of the screen. The use of foldable ultra-thin glass provides another possibility for improving the impact resistance of foldable screens. However, the thickness of foldable ultra-thin glass is usually less than 100 μm. After chemical strengthening, its central tension is high, and when subjected to external impact, there is still a high possibility of breaking. Compared with the impact resistance of the traditional glass cover substrate, there is still a big gap.

Based on the above, the development of a flexible display cover substrate with excellent bending performance, scratch resistance and impact resistance is an important topic that needs to be studied at present.

### SUMMARY OF THE INVENTION

In view of the above technical problems, an object of the present invention is to provide a flexible display cover substrate, which has both good scratch resistance and impact resistance without affecting the bending resistance.

To achieve the above object, the present invention provides a flexible display cover substrate, which includes an ultra-thin glass; a plastic film disposed on the ultra-thin glass; an anti-fouling layer disposed on the plastic film; an impact-resistant layer disposed on at least one surface of the ultra-thin glass or the plastic film, wherein the impact-resistant layer includes a disperse phase and a continuous phase, a percentage of the disperse phase in the impact-resistant layer is 10-50 wt %, an elastic modulus ratio of the disperse phase to the continuous phase is greater than or equal to 70, and an elastic modulus of the impact-resistant layer is greater than or equal to 1 GPa; and an adhesive layer disposed between the ultra-thin glass and the plastic film, wherein an elastic modulus of the adhesive layer is greater than or equal to 0.1 GPa.

Preferably, an elastic modulus of the plastic film is greater than or equal to 3 GPa.

Preferably, the impact-resistant layer is disposed at a lower surface of the ultra-thin glass and opposite to the plastic film. More preferably, the adhesive layer serves as a first adhesive layer, the flexible display cover substrate further includes a second adhesive layer, and the impact-resistant layer is adhered to the lower surface of the ultra-thin glass through the second adhesive layer.

Preferably, the impact-resistant layer is disposed between the anti-fouling layer and the plastic film.

Preferably, the impact-resistant layer is disposed at a lower surface of the plastic film, and the impact-resistant layer is adhered to the ultra-thin glass through the adhesive layer.

Preferably, the impact-resistant layer is formed of an impact-resistant composition, which includes a multifunctional (meth)acrylate compound, an initiator and nanoparticles.

Preferably, a water drop angle of the anti-fouling layer is greater than or equal to 100 degrees.

Preferably, the anti-fouling layer is formed of an anti-fouling composition, which includes a hydrophobic photocurable resin, an antistatic agent, a compound having three or more reactive functional groups, an elastic oligomer, an initiator, and modified inorganic nano-particles, and a weight ratio of the compound having three or more reactive functional groups to the elastic oligomer ranges from 0.25 to 3.

Preferably, a thickness of the plastic film is less than or equal to 50 microns.

Preferably, a thickness of the adhesive layer is less than or equal to 15 microns.

Preferably, the hydrophobic photocurable resin includes a fluorine-based photocurable resin or a fluorine-polysilicone-based photocurable resin.

Preferably, the antistatic agent includes an organic salt compound.

Preferably, the compound having three or more reactive functional groups includes a compound having three or more (meth)acrylate groups.

Preferably, the elastic oligomer includes an oligomer of polyurethane (meth)acrylate or an oligomer of polyurethane (meth)acrylate containing silicon.

Preferably, the modified inorganic nano-particles include inorganic nano-particles modified with a silane coupling agent.

Preferably, the flexible display cover substrate is able to withstand a pen drop strength of greater than or equal to 5 cm.

Preferably, the flexible display cover substrate is able to withstand a ball drop strength of greater than or equal to 50 cm.

Preferably, the flexible display cover substrate has a thickness of less than or equal to 110 μm.

Preferably, the flexible display cover substrate has a folding resistance that can withstand an inner folding of R=3 mm for 200,000 times, wherein R is a bending radius.

Preferably, the flexible display cover substrate has a scratch resistance that can withstand steel wool scratching for 2,500 reciprocating times.

According to the present invention, a flexible display cover substrate that has both good scratch resistance and impact resistance without excessively compromising (or even without compromising at all) the bending resistance can be obtained.

### BRIEF DESCRIPTION OF THE DRAWINGS

FIG. 1 is a schematic view showing a flexible display cover substrate according to a first embodiment of the present invention.

FIG. 2 is a schematic view showing a flexible display cover substrate according to a second embodiment of the present invention.

FIG. 3 is a schematic view showing a flexible display cover substrate according to a third embodiment of the present invention.

FIG. 4 is a schematic view showing a flexible display cover substrate according to a fourth embodiment of the present invention.

### LEGEND

100 flexible display cover substrate
10 ultra-thin glass
10b lower surface
15 adhesive layer
20 plastic film
30 anti-fouling layer
40 impact-resistant layer
200 flexible display cover substrate
110 ultra-thin glass
110b lower surface
115 first adhesive layer
117 second adhesive layer
120 plastic film
130 anti-fouling layer
140 impact-resistant layer
300 flexible display cover substrate
210 ultra-thin glass
215 adhesive layer
220 plastic film
220a upper surface
230 anti-fouling layer
240 impact-resistant layer
400 flexible display cover substrate
310 ultra-thin glass
315 adhesive layer
320 plastic film
320b lower surface
330 anti-fouling layer
340 impact-resistant layer

### DETAILED DESCRIPTION OF THE EMBODIMENTS

The range represented by “a value to another value” herein is a summary representation method that avoids listing all the values in the range one by one in the specification. Therefore, the description of a specific numerical range covers arbitrary values in the numerical range and a smaller numerical range defined by any values in the numerical range, just as if the arbitrary values and the smaller numerical range were written in the specification. Below, the embodiments are specifically cited as examples to illustrate that the present invention can indeed be implemented. However, these embodiments are only illustrative, and the present invention is not limited thereto.

The present invention provides a flexible display cover substrate, which includes an ultra-thin glass; a plastic film disposed on the ultra-thin glass; an anti-fouling layer disposed on the plastic film; an impact-resistant layer disposed on at least one surface of the ultra-thin glass or the plastic film, wherein the impact-resistant layer includes a disperse phase and a continuous phase, a percentage of the disperse phase in the impact-resistant layer is 10-50 wt %, an elastic modulus ratio of the disperse phase to the continuous phase is greater than or equal to 70, and an elastic modulus of the impact-resistant layer is greater than or equal to 1 GPa; and an adhesive layer disposed between the ultra-thin glass and the plastic film, wherein an elastic modulus of the adhesive layer is greater than or equal to 0.1 GPa.

### <Flexible Display Cover Substrate>

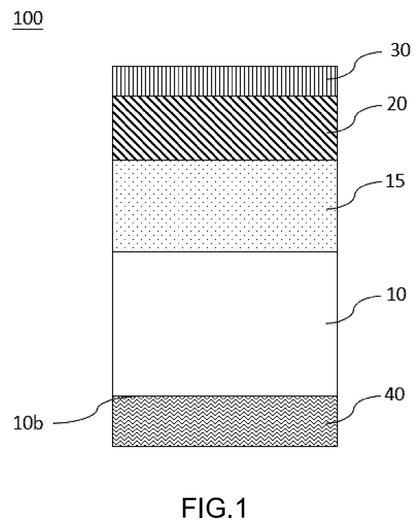

Please refer to FIG. 1, which schematically illustrates a flexible display cover substrate 100 according to a first embodiment of the present invention. The flexible display cover substrate 100 includes an ultra-thin glass 10; a plastic film 20, which is located on the ultra-thin glass 10; an anti-fouling layer 30, which is located on the plastic film 20; and an impact-resistant layer 40, wherein the ultra-thin glass 10 is adhered to the plastic film 20 through an adhesive layer 15, and the impact-resistant layer 40 is disposed on a lower surface 10b of the ultra-thin glass 10 and is opposite to the plastic film 20.

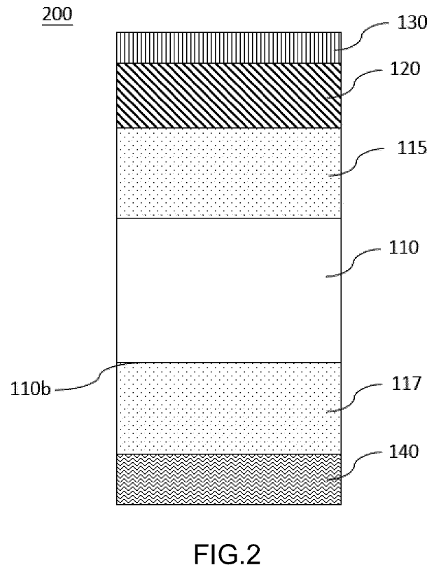

Please refer to FIG. 2, which schematically illustrates a flexible display cover substrate 200 according to a second embodiment of the present invention. This embodiment is extended based on the flexible display cover substrate 100 of the first embodiment. The adhesive layer 15 described in the first embodiment is named as a first adhesive layer 115 in this embodiment. The flexible display cover substrate 200 in this embodiment further includes a second adhesive layer 117. A impact-resistant layer 140 is adhered to a lower surface 110b of an ultra-thin glass 110 through the second adhesive layer 117. The first adhesive layer 115 and the second adhesive layer 117 may be the same or different, that is, the adhesive used may be the same or different, and examples of the adhesive are described below.

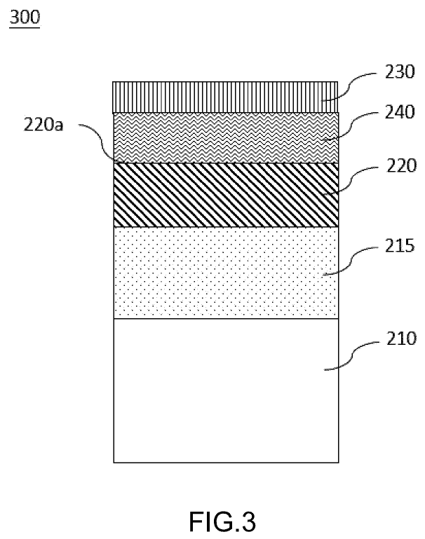

Please refer to FIG. 3, which schematically illustrates a flexible display cover substrate 300 according to a third embodiment of the present invention. The third embodiment is substantially the same as the flexible display cover substrate of the first embodiment. In the third embodiment, an impact-resistant layer 240 is located on a plastic film 220, and specifically, the impact-resistant layer 240 is disposed on an upper surface 220a of the plastic film 220. In this embodiment, an anti-fouling layer 230 is located on the impact-resistant layer 240.

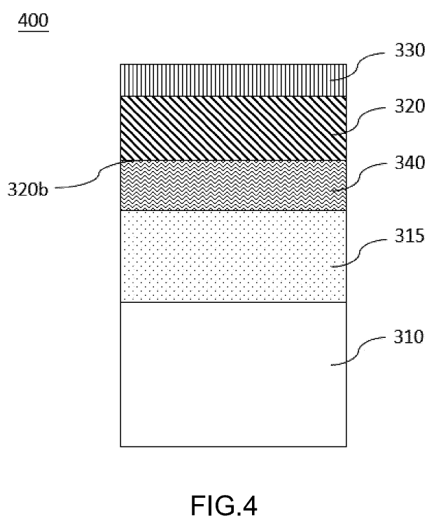

Please refer to FIG. 4, which schematically illustrates a flexible display cover substrate 400 according to a fourth embodiment of the present invention. The fourth embodiment is substantially the same as the flexible display cover substrate of the first embodiment. In the fourth embodiment, an impact-resistant layer 340 is located under a plastic film 320. Specifically, the impact-resistant layer 340 is disposed on a lower surface 320b of the plastic film 320. In this embodiment, in terms of the overall layer stack, the flexible display cover substrate 400 includes an ultra-thin glass 310; an adhesive layer 315, which is located on the ultra-thin glass 310; an impact-resistant layer 340, which is located on the adhesive layer 315; a plastic film 320, which is located on the impact-resistant layer 340; and an anti-fouling layer 330, which is located on the plastic film 320.

### <Anti-Fouling Layer>

In the present invention, the anti-fouling layer may be a multi-layer laminate or a single coating. The anti-fouling layer is preferably formed by an anti-fouling composition. More specifically, the anti-fouling layer is formed by coating the anti-fouling composition to form a coating, which is then cured by heating or light curing to form the anti-fouling layer.

The anti-fouling composition may include a hydrophobic photocurable resin, an antistatic agent, a compound having three or more reactive functional groups, an elastic oligomer, an initiator, and modified inorganic nano-particles, and the weight ratio of the compound having three or more reactive functional groups to the elastic oligomer ranges from 0.25 to 3. The anti-fouling layer formed by the anti-fouling composition may have both anti-fouling and wear-resistant properties.

Based on the total weight of the anti-fouling composition, the total content of the compound having three or more reactive functional groups, the elastic oligomer and the initiator is preferably 10 wt % to 95 wt %, for example, 15 wt % to 90 wt %. The content of the hydrophobic photocurable resin is preferably 0.1 wt % to 10 wt %, based on the total weight of the anti-fouling composition. In a preferred embodiment, the anti-fouling composition does not contain the fluorescent colorant.

In a preferred embodiment, the water drop angle of the anti-fouling layer is greater than or equal to 100 degrees, such as 101 degrees, 102 degrees, 103 degrees or 104 degrees. In a more preferred embodiment, the water drop angle of the anti-fouling layer is greater than or equal to 105 degrees, such as 106 degrees or 107 degrees. In a preferred embodiment, the thickness of the anti-fouling layer is between 2 and 10 microns, for example 2, 3, 4 or 7 microns.

In the present invention, examples of the hydrophobic photocurable resin include, but are not limited to, a fluorine-based photocurable resin or a fluorine-polysilicone-based photocurable resin. The fluorine-based photocurable resin may be a fluorine-based acrylic monomer. The fluorine-polysilicone-based photocurable resin may be a fluorine-polysilicone-based acrylic monomer.

Examples of the antistatic agent suitable for the present invention include, but are not limited to, cationic copolymers with quaternary ammonium salt groups on the side groups, anionic compounds containing polystyrene sulfonic acid, compounds with poly(alkylene oxide) chains (preferably poly(ethylene oxide) chains, poly(propylene oxide) chains), nonionic polymers (such as polyethylene glycol methacrylate copolymers, polyether ester amides, polyether amide imides, polyether esters, ethylene oxide-epichlorohydrin copolymers), and IT-conjugated conductive polymers. They can be used alone or in combination of two or more. In a preferred embodiment, the antistatic agent is an organic salt compound. In a more preferred embodiment, the antistatic agent is an organic salt compound with a conductivity of ≥0.1 mS/cm.

Examples of compounds having three or more reactive functional groups suitable for use in the present invention include a compound having three or more (meth)acrylate groups, examples of which include, but are not limited to, dipentaerythritol hexaacrylate, pentaerythritol triacrylate, dipentaerythritol triacrylate, dipentaerythritol acrylate, pentaerythritol hexaacrylate, trimethylolpropane triacrylate, trimethylallyl isocyanurate, triallyl isocyanurate, tetramethyltetravinylcyclotetrasiloxane, ethoxylated trimethylolpropane triacrylate (TMPEOTA), propoxylated glycerol triacrylate (GPTA), pentaerythritol tetraacrylate (PETA), pentaerythritol tri(meth)acrylate, pentaerythritol tetra(meth)acrylate, dipentaerythritol penta(meth)acrylate, pentaerythritol tri(meth)acrylate, dipentaerythritol penta(meth)acrylate, and tripentaerythritol hepta(meth)acrylate. The above compounds may be used alone or in combination of two or more, depending on the needs.

In the present invention, examples of the elastic oligomer include an oligomer of polyurethane (meth)acrylate or an oligomer of polyurethane (meth)acrylate containing silicon, which can be formed by the reaction of hydroxyl (meth)acrylate and diisocyanate. Among them, hydroxyl (meth)acrylate can be synthesized from (meth)acrylate or propenyl-containing compound and polyol. The (meth)acrylate may be methyl (meth)acrylate, ethyl (meth)acrylate, isopropyl (meth)acrylate, butyl (meth)acrylate, or cyclohexyl (meth)acrylate. The polyol may be ethylene glycol, 1,3-propylene glycol, diethylene glycol, neopentyl glycol, 1,4-butanediol, 1,6-hexanediol, 1,5-pentanediol, trimethylolpropane, glycerol, 1,3,5-triol, pentaerythritol, or dipentaerythritol, etc. The diisocyanate may be hexamethylene diisocyanate, 2,4-toluene diisocyanate, xylene diisocyanate, trimethyl hexamethylene diisocyanate, 4-diphenylmethane diisocyanate, or 1,5-naphthalene diisocyanate, etc. Commercially available polyurethane (meth)acrylate oligomers may also be used, for example, U-2PPA, U10-HA, U10-PA, UA-1100H, UA-15HA, UA-33H, U-200PA, UA-290TM, UA-160TM and UA-122P, etc. produced by Shin-Nakamura Chemical; UO22-081, UO26-001, UO22-162, UO52-002, UO26-012 and UO22-312, etc. produced by Risheng Chemical. The molecular weight of the elastic oligomer is preferably 500 g/mol to 5000 g/mol, such as 520 g/mol to 4800 g/mol or 550 g/mol to 4500 g/mol. The content of the elastic oligomer is preferably 0.1 wt % to 80 wt %, based on the total weight of the anti-fouling composition.

Examples of the initiator suitable for the present invention include photoinitiators or thermal initiators, which can be used alone or in combination of two or more. There is no particular limitation on the amounts of the compound having three or more reactive functional groups and the initiator. Generally speaking, the composition ratio (weight ratio) of the compound having three or more reactive functional groups and the initiator is preferably 5:1 to 100:1. In addition, based on the total weight of the anti-fouling composition, the content of the compound having three or more reactive functional groups, the elastic oligomer and the initiator is, for example, 10 wt % to 95 wt %. If the amount of the initiator is above the lower limit, the degree of polymerization can be maintained at a certain level, so that the polymer formed by the monomer retains the characteristics of a polymer. If the amount of the initiator is below the upper limit, the polymer formed by the monomer does not have the problem of being too brittle due to excessive polymerization. If the amount of the monomer having a UV curing group is too low, the crosslinking degree of the polymer will be insufficient to be cured. If the proportion of the monomer having a UV curing group is too high, the polymer will be brittle.

Examples of the photoinitiator suitable for the present invention include, but are not limited to, acetophenones; benzoins; diphenyl ketones; thioxanthones; and anthraquinones. In addition to being used alone, the above photoinitiators can also be mixed in combination of two or more, depending on the needs of the user. For example, in order to obtain a fast photosensitivity, the isopropyl thioxanthone can be mixed with 2-methylphenyl-2-(dimethylamino)-1-[4-(morpholinyl)phenyl]-1-butyl-1-one and used as a photoinitiator.

Examples of the thermal initiator suitable for the present invention include, but are not limited to, azos; and peroxides. In addition to being used alone, the above thermal initiators can also be mixed in combination of two or more, depending on the needs.

The modified inorganic nano-particles can be obtained by reacting the reaction components including unmodified inorganic nano-particles and the modifier. In the reaction components, the content of the unmodified inorganic nano-particles is preferably 90 to 98 wt %; and the content of the modifier is preferably 2 to 10 wt %. The unmodified inorganic nano-particles suitable for the present invention include, but are not limited to, inorganic metal oxide nano-particles, such as titanium dioxide, silicon dioxide, zirconium oxide, zinc oxide, and aluminum oxide. The modifier suitable for the present invention may be a silane coupling agent, which is an organosilicon compound containing chlorosilane, alkoxysilane, or silazane. The functional groups contained in the silane coupling agent may include vinyl, methacryloxy, acryloxy, amino, ureido, chloropropyl and mercapto groups, polysulfide and isocyanate, but are not limited thereto. Examples of the silane coupling agent may include, but are not limited to, vinyl trichlorosilane, vinyl trimethoxysilane, vinyl triethoxysilane, 3-methacryloxypropyl-methyldimethoxysilane, 3-methacryloxypropyl-trimethoxysilane, 3-methacryloxypropyl-methyldiethoxysilane, 3-methacryloxypropyl-triethoxysilane, 3-acryloxypropyltrimethoxysilane, N-(2-aminoethyl)-3-aminopropylmethyl dimethoxysilane, N-(2-aminoethyl)-3-aminopropyltrimethoxysilane, N-(2-aminoethyl)-3-aminopropyltriethoxysilane, 3-aminopropyltrimethoxysilane, 3-aminopropyltriethoxysilane, N-phenyl-3-aminopropyltrimethoxysilane, 3-chloropropyltriethoxysilane, 3-mercaptopropyltrimethoxysilane, bis(triethoxysilylpropyl) tetrasulfide and 3-isocyanatepropyltriethoxysilane.

In the present invention, the content of the modified inorganic nano-particles is preferably 0.1 wt % to 60 wt %, based on the total weight of the anti-fouling composition.

### <Plastic Film>

The plastic film of the present invention may be a transparent plastic film such as PI, cycloolefin copolymer (COC), PET, PC, Polyethylene Naphthalate (PEN), Polysulfone (PSO), TAC, PMMA, thermoplastic polyurethane (TPU), etc. The plastic film composite formed by the above transparent plastic film can also be used as the plastic film of the present invention. The surface of the plastic film may be treated by the following methods: plasma, corona, primer coating treatment, etc. The thickness of the plastic film is preferably less than or equal to 50 microns, more preferably between 13 and 50 microns. The elastic modulus of the plastic film is preferably greater than or equal to 3 GPa.

### <Adhesive Layer>

As to the required properties of the adhesive layer, in addition to the basic adhesion and viscoelasticity, the inventors unexpectedly discovered that if the adhesive layer has a high elastic modulus, the scratch resistance and impact resistance of the flexible display cover substrate can be improved. The flexible display cover substrate of the present invention is a composite film, and its hardness can be obtained by multiplying the hardness of each layer by a specific parameter and then summing them. The hardness of one layer increases with the increase of its elastic modulus, so the use of an adhesive layer with a high elastic modulus can increase the hardness of the display cover. When the composite film flexible display cover substrate is subjected to impact resistance testing, the depth of the indentation on the cover substrate by a falling pen or a falling ball will also decrease as the elastic modulus of each layer increases. The elastic modulus of the adhesive layer of the present invention is greater than or equal to 0.1 GPa. Such a high elastic modulus will increase the internal stress, especially when the bending radius is small, the deformation ratio of the adhesive layer is greater than or equal to 100%. Excessive internal stress will cause the adhesive layer to debond or generate bubbles. Therefore, the adhesive force of the adhesive layer is preferably greater than or equal to 10 N/10 mm, and the elongation of the adhesive layer is preferably greater than or equal to 350%.

The adhesive layer is formed by an adhesive, and the adhesive may include a main adhesive, a curing agent, an auxiliary agent and a solvent. The main adhesive may include one or more high-adhesive resins, which may be selected from rubber, acrylic acid, polyurethane or silicone. The high-adhesive resin may contain one or more chemically active groups. Corresponding to the type of chemically active group, a corresponding curing agent and/or catalyst is added, for example, a hydroxyl-containing resin can be used with an isocyanate curing agent; a carboxylic acid-containing resin can be used with an epoxy curing agent; an acrylic-based UV resin can be used with a photoinitiator. According to the chemical reaction characteristics of the combination of the active group and the curing agent, a suitable catalyst may be selected.

Commercially available adhesives suitable for the present invention can be selected, for example: 3M CEF series, Nitto FL series, Tesa 6973 series, Shintack Chemical EA series, AICA AITRON series, Shin-Etsu Chemical KCT series or adhesive products from Showa, OJI, and Shinron.

### <Ultra-Thin Glass>

The ultra-thin glass is an ultra-thin flexible glass cover substrate, a special glass material used in mobile phones with a foldable screen, having high hardness, scratch resistance, no creases when bent, good touch, but more fragile than CPI, and usually used in conjunction with the explosion-proof film when applied to the display cover.

### <Impact-Resistant Layer>

The flexible display cover substrate of the present invention includes at least one impact-resistant layer, which is disposed on at least one surface of the ultra-thin glass or the plastic film. The impact-resistant layer may be formed by an impact-resistant composition. More specifically, the impact-resistant layer is formed by coating the impact-resistant composition to form a coating, which is then cured by heating or light curing to form the impact-resistant layer.

The impact-resistant layer composition preferably includes one or more multifunctional (meth)acrylate compounds; a photoinitiator; and nano-particles. The impact-resistant layer includes a cured product formed by one or more multifunctional (meth)acrylates; and a mixture of particles dispersed in the cured product. The inorganic nano-particles suitable for the present invention include, but are not limited to, inorganic metal oxide nano-particles such as titanium dioxide, silicon dioxide, zirconium oxide, zinc oxide and aluminum oxide. Such nano-particles may have a substantially mono-dispersed size distribution, and the oxide particles are non-aggregated (substantially discrete). The multifunctional (meth)acrylate compound refers to a compound having multiple (meth)acrylate groups.

The total concentration of the particle mixture may range from 10 wt % to 50 wt % of the total solids. The particles may be composed of a single oxide (e.g., silicon dioxide), or of multiple (e.g., two or three) oxides, or may be composed of core-shell particles, i.e., a metal oxide serving as the core (or a material other than a metal oxide as the core), and another type of metal oxide deposited on the surface of the core serving as the shell. The inorganic oxide particles may be provided in the form of a sol containing a colloidal dispersion of inorganic oxide particles, often in a liquid medium. The sol may be prepared using various techniques and in various forms, including aqueous sols (where water is used as the liquid medium), organic sols (where organic solvents are used as the liquid medium), and mixed sols (where the liquid medium contains both water and the organic liquid).

The thickness of the impact-resistant layer is preferably less than or equal to 15 microns, and more preferably between 1 and 15 microns. The microphase separation structure or nanoscale phase separation structure of the impact-resistant layer is composed of disperse phase particles dispersed in a continuous phase UV-curable resin. The elastic modulus of the continuous phase may be relatively low, and the elastic modulus of the disperse phase may be relatively high. Preferably, the ratio of the elastic modulus of the disperse phase to the continuous phase is greater than or equal to 70, and the elastic modulus of the impact-resistant layer is greater than or equal to 1 GPa. The elastic modulus ratio of the disperse phase to the continuous phase is more preferably between 70 and 380, such as: 70-370 or 70-360. The elastic modulus of the impact-resistant layer is more preferably between 1 GPa and 3 GPa. The disperse phase may be nanoparticles, preferably inorganic nano-particles, including but not limited to: titanium dioxide, silicon dioxide, zirconium oxide, zinc oxide and aluminum oxide.

In the present invention, the roughness of the film surface of the impact-resistant layer of the flexible display cover substrate is less than or equal to 20 nm. Preferably, the haze of the flexible display cover substrate of the present invention is increased less than or equal to 0.5, compared to the flexible display cover substrate without the impact-resistant layer.

In the present invention, the flexible display cover substrate can preferably withstand a pen falling strength greater than or equal to 5 cm, and more preferably can withstand a pen falling strength greater than or equal to 6 cm. The flexible display cover substrate can preferably withstand a ball falling strength greater than or equal to 50 cm, and more preferably can withstand a ball falling strength greater than or equal to 55 cm.

In the present invention, the thickness of the flexible display cover substrate is preferably less than or equal to 110 microns.

Below, the present invention is described in detail through Examples and Comparative Examples. However, the following Examples and Comparative Examples are not intended to limit the present invention.

### PREPARATION EXAMPLES

### Preparation Example 1: Preparation of Coating Solution for Impact Resistance (IR) Layer

According to the weight ratio listed in Table 1 below, a specific weight of 15(ethoxy)trimethylolpropane triacrylate (15EO-TMPTA) and a specific weight of polydipentaerythritol hexaacrylate (DPHA) were added to propylene glycol monomethyl ether acetate (PGMEA) and stirred for 30 minutes. Afterwards, a specific weight of 50 wt % nanoparticle dispersion was mixed with 2-methyl-1-(4-(methylthiol) phenyl-2-morpholinylpropyl ketone (184) and a leveling agent (BYK3535), and stirred for 60 minutes to obtain the coating solution required for the subsequent Examples and Comparative Examples. The proportions of 2-methyl-1-(4-(methylthiol)phenyl-2-morpholinylpropyl ketone and BYK3535 in the total solid content were 3.5 wt % and 0.1 wt %, respectively, and the solid content of the impact-resistant coating solution was 40 wt %. Except for Comparative Example 4, which used acrylic resin (MX180TA from Wada) as the disperse phase, the others used silica (MEK-ST-40 from Nissan) as the disperse phase.

### Preparation Example 2: Preparation of Anti-Fouling (AF) Layer

The modified inorganic nano-particles in the anti-fouling layer were obtained by the following method: silica nano-particles (Nissan/MEK-ST-40) were diluted with methyl ethyl ketone (MEK) to form a 0.5 wt % solution. 1 part by weight of a silica nanoparticle solution with a solid content of 0.5 wt % was mixed with 0.001 part by weight of 3-methacryloxypropyl-trimethoxysilane and heated at 50° C. under nitrogen for 4 hours for modification synthesis. After the reaction was completed, the temperature was lowered to room temperature, 1 part by weight of the modified nanoparticle solution was added to 0.133 parts by weight of polydipentaerythritol hexaacrylate and 0.133 parts by weight of elastic oligomer UA160-TM and stirred for 30 minutes, and then the solution was phase-transferred according to the required solvent. Finally, a solution formed by mixing 1.5 parts by weight of modified inorganic nanoparticles and monomers having unsaturated bonds was mixed with 0.012 parts by weight of 2-methyl-1-(4-(methylthiol)phenyl-2-morpholinylpropyl ketone and 0.001 parts by weight of a leveling agent, followed by adjustment using ethyl acetate as a solvent to obtain a final solid content of 55% by weight. 20 g of this solution were taken, to which 1.1 g of Fluorolink AD1700 (10 wt % dissolved in butanone) serving as a hydrophobic acrylic monomer and 1.1 g of Antistatic 681 (10 wt % dissolved in butanone) serving as an antistatic agent were added, and then mixed and stirred for 30 minutes, then spin-coated on the surface of the PI film (Mpior of Microcosm Technology CO., LTD.) at 250 rpm for 10 seconds, soft-baked at 90° C. for 5 minutes, and then exposed and cured at 4000 mJ/cm² to obtain the “AF/Mpior” sample. In Comparative Example 7, polyurethane elastomer (SNY97 of Dacang) was used to replace Mpior of Microcosm Technology CO., LTD.

### EXAMPLES/COMPARATIVE EXAMPLES

The aforementioned impact-resistant coating solution was taken and coated on the UTG surface, during which the thickness of the impact-resistant layer was controlled with wire rods of different numbers, then soft-baked at 100° C. for 5 minutes, and exposed and cured under ultraviolet light of 4000 mJ/cm² to obtain the “UTG/IR” sample. The plastic film surface of the “AF/Mpior” sample was coated with Shin-Etsu Chemical KCT171 adhesive (Adhesive; AD), and soft-baked at 80° C. for 5 minutes to obtain the “AF/Mpior/AD” sample. Next, the “AF/Mpior/AD” sample was pressed together with the “UTG/IR” sample to obtain the “AF/Mpior/AD/UTG/IR” laminated flexible display cover substrate. In Comparative Example 10, Showa ELX-7900 was used to replace Shin-Etsu Chemical KCT171 adhesive.

### Performance Evaluation

### Thickness Measurement

The thickness of each substrate was measured by contact with a thickness gauge, and then the thickness of the coating plus the substrate was measured. The thickness of the coating could be obtained by subtracting the former from the latter.

### Steel Wool Scratch Test

A piece of 2×2 cm steel wool SW #0000 was used to scratch a fixed area of the cover substrate under a load of 1,000 g at a speed of 40 times/min for 2,500 times using a reciprocating wear tester, and then the water drop angle of the scratched area was measured. When the water drop angle was greater than or equal to 100 degrees, it was recorded as O, and when the water drop angle was less than 100 degrees, it was recorded as X.

### Mechanical Property Testing of Materials

According to ASTM-D638 standard test method, the mechanical properties of the film layer, such as elastic modulus and elongation, were measured using a universal tensile testing machine.

### Total Light Transmittance (%) and Haze

According to ASTM D1007, the total light transmittance and haze of the cover substrate were measured using Nippon Denshoku DOH 5500.

### Roughness Measurement

According to ISO 25178 standard test method, the roughness of the film layer was measured using a white light interferometer.

### Bending Resistance Test

The cover substrate was attached to a folding tester (Tension-Free U-shape Folding manufactured by YUASA System) and folded 200,000 times with an inner fold of R=3 mm or an outer fold of R=4 mm (where R refers to the bending radius). First, check whether the cover substrate had breakage or not, and then check whether the cover substrate had cracking or not with the naked eye and a microscope. Any case where the cover substrate had breakage or cracking was marked as unqualified (X), and the case where there was neither breakage nor cracking was marked as qualified (O).

### Pen Drop Test

The cover was placed on marble, and a pen with a weight of 12.8 g and a pen tip diameter of 0.5 mm was dropped on the cover from a certain height with the pen tip hitting the cover. The height of the cover glass breaking was used to determine the pen drop resistance.

### Ball Drop Test

The cover was placed on marble, and a steel ball with a weight of 32.6 g and a radius of 20 mm was dropped on the cover from a certain height. The height of the cover glass breaking was used to determine the ball drop resistance.

The test results of the above performance evaluation are recorded in Table 1.

TABLE 1

| | | Test No. | | | | | |
|---|---|---|---|---|---|---|---|
| | | | | | | | Comparative |
| | | Example 1. | Example 2. | Example 3. | Example 4 | Example 5. | Example 1. |
| Properties | Coating | Al-1 | Al-2 | Al-3 | Al-3 | Al-3 | None |
| of impact- | solution No. | | | | | | |
| resistant | of impact- | | | | | | |
| layer | resistant layer | | | | | | |
| | Disperse phase | nanoSiO2/10 | nanoSiO2/15 | nanoSiO2/50 | nanoSiO2/50 | nanoSiO2/50 | |
| | (type/content(wt %)) | | | | | | |
| | Continuous phase | TMPTA15EO/ | TMPTA15EO/ | TMPTA15EO/ | TMPTA15EO/ | TMPTA15EO/ | |
| | (composition/ | DPHA = 7/3 | DPHA = 7/3 | DPHA = 8/2 | DPHA = 8/2 | DPHA = 8/2 | |
| | content) | | | | | | |
| | Modulus ratio | 70/1 = 70 | 70/1 = 70 | 70/1 = 70 | 70/1 = 70 | 70/1 = 70 | |
| | of “disperse | | | | | | |
| | phase/continuous | | | | | | |
| | phase” | | | | | | |
| | Modulus of | 1.2 | 1.5 | 1.5 | 1.5 | 1.5 | |
| | impact-resistant | | | | | | |
| | layer (GPa) | | | | | | |
| | Thickness of | 5.0 | 5.0 | 5.0 | 15.0 | 5.0 | |
| | impact-resistant | | | | | | |
| | layer (μm) | | | | | | |
| Cover | Cover materials | AF/Mpior/ | AF/Mpior/ | AF/Mpior/ | AF/Mpior/ | AF/Mpior/ | AF/Mpior/ |
| | (and structure) | AD/UTG/IR | AD/UTG/IR | AD/UTG/IR | AD/UTG/IR | AD/UTG/IR | AD/UTG |
| | Thickness of | 3/13/15/ | 3/13/15/ | 3/13/15/ | 3/13/15/ | 3/50/15/ | 3/13/15/30 |
| | cover (each | 30/5 | 30/5 | 30/5 | 30/15 | 30/5 | |
| | layer in the | | | | | | |
| | structure) (μm) | | | | | | |
| | Modulus of | 3.8 | 3.8 | 3.8 | 3.8 | 3.8 | 3.8 |
| | plastic | | | | | | |
| | film (GPa) | | | | | | |
| | Modulus of | 0.23 | 0.23 | 0.23 | 0.23 | 0.23 | 0.23 |
| | adhesive | | | | | | |
| | layer (GPa) | | | | | | |
| | Total thickness | 66.00 | 66.00 | 66.00 | 76.00 | 103.00 | 66.00 |
| | (μm) | | | | | | |
| Test | Haze | 0.37 | 0.57 | 0.57 | 0.57 | 0.57 | 0.37 |
| results | Roughness | <10 nm | <10 nm | <10 nm | <10 nm | <10 nm | <10 nm |
| of cover | (impact-resistant | | | | | | |
| | layer surface) | | | | | | |
| | Pen drop height | 6 | 6 | 6 | 6 | 7 | 2 |
| | (UTG breakage) | | | | | | |
| | Ball drop height | 55 | 55 | 55 | 55 | 59 | 4 |
| | (UTG breakage) | | | | | | |
| | Bending | (Inner fold | (Inner fold | (Inner fold | (Inner fold | (Inner fold | (Inner fold |
| | resistance | R3 × 200,000 | R3 × 200,000 | R3 × 200,000 | R3 × 200,000 | R3 × 200,000 | R3 × 200,000 |
| | | times) | times) | times) | times) | times) | times) |
| | | ◯ | ◯ | ◯ | ◯ | ◯ | ◯ |
| | | (Outer fold | (Outer fold | (Outer fold | (Outer fold | (Outer fold | (Outer fold |
| | | R4 × 200,000 | R4 × 200,000 | R4 × 200,000 | R4 × 200,000 | R4 × 200,000 | R4 × 200,000 |
| | | times) | times) | times) | times) | times) | times) |
| | | ◯ | ◯ | ◯ | ◯ | ◯ | ◯ |
| | Steel wool scratch | ◯ | ◯ | ◯ | ◯ | ◯ | ◯ |
| | (Reciprocating | | | | | | |
| | 2,500 times) | | | | | | |

| | | Test No. | | | | |
|---|---|---|---|---|---|---|
| | | Comparative | Comparative | Comparative | Comparative | Comparative |
| | | Example 2. | Example 3. | Example 4. | Example 5. | Example 6. |
| Properties | Coating | Al-4 | Al-5 | Al-6 | Al-3 | Al-5 |
| of impact- | solution No. | | | | | |
| resistant | of impact- | | | | | |
| layer | resistant layer | | | | | |
| | Disperse phase | nanoSiO2/5 | nanoSiO2/10 | MX180TA/10 | nanoSiO2/50 | nanoSiO2/50 |
| | (type/content(wt %)) | | | | | |
| | Continuous phase | TMPTA15EO/ | TMPTA15EO/ | TMPTA15EO/ | TMPTA15EO/ | TMPTA15EO/ |
| | (composition/ | DPHA = 8/2 | DPHA = 9.5/0.5 | DPHA = 6/4 | DPHA = 8/2 | DPHA = 6/4 |
| | content) | | | | | |
| | Modulus ratio | 70/1 = 70 | 70/1 = 70 | 2/1 = 2 | 70/1 = 70 | 70/1 = 70 |
| | of “disperse | | | | | |
| | phase/continuous | | | | | |
| | phase” | | | | | |
| | Modulus of | 1.3 | 0.9 | 1.1 | 1.5 | 1.6 |
| | impact-resistant | | | | | |
| | layer (GPa) | | | | | |
| | Thickness of | 5.0 | 5.0 | 5.0 | 17.5 | 5.0 |
| | impact-resistant | | | | | |
| | layer (μm) | | | | | |
| Cover | Cover materials | AF/Mpior/ | AF/Mpior/ | AF/Mpior/ | AF/Mpior/ | AF/Mpior/ |
| | (and structure) | AD/UTG/IR | AD/UTG/IR | AD/UTG/IR | AD/UTG/IR | AD/UTG/IR |
| | Thickness of | 3/13/15/ | 3/13/15/ | 3/13/15/ | 3/13/15/ | 3/13/15/ |
| | cover (each | 30/5 | 30/5 | 30/5 | 30/5 | 30/5 |
| | layer in the | | | | | |
| | structure) (μm) | | | | | |
| | Modulus of | 3.8 | 3.8 | 3.8 | 3.8 | 3.8 |
| | plastic | | | | | |
| | film (GPa) | | | | | |
| | Modulus of | 0.23 | 0.23 | 0.23 | 0.23 | 0.23 |
| | adhesive | | | | | |
| | layer (GPa) | | | | | |
| | Total thickness | 66.00 | 66.00 | 66.00 | 78.50 | 66.00 |
| | (μm) | | | | | |
| Test | Haze | 0.25 | 0.39 | 0.60 | 0.70 | 2.23 |
| results | Roughness | <10 nm | <10 nm | 100 nm | <10 nm | <10 nm |
| of cover | (impact-resistant | | | | | |
| | layer surface) | | | | | |
| | Pen drop height | 2 | 2 | 2 | 7 | 6 |
| | (UTG breakage) | | | | | |
| | Ball drop height | 4 | 4 | 4 | 60 | 55 |
| | (UTG breakage) | | | | | |
| | Bending | (Inner fold | (Inner fold | (Inner fold | (Inner fold | (Inner fold |
| | resistance | R3 × 200,000 | R3 × 200,000 | R3 × 200,000 | R3 × 200,000 | R3 × 200,000 |
| | | times) | times) | times) | times) | times) |
| | | ◯ | ◯ | ◯ | X | ◯ |
| | | (Outer fold | (Outer fold | (Outer fold | (Outer fold | (Outer fold |
| | | R4 × 200,000 | R4 × 200,000 | R4 × 200,000 | R4 × 200,000 | R4 × 200,000 |
| | | times) | times) | times) | times) | times) |
| | | ◯ | ◯ | ◯ | X | ◯ |
| | Steel wool scratch | ◯ | ◯ | ◯ | ◯ | ◯ |
| | (Reciprocating | | | | | |
| | 2,500 times) | | | | | |

| | | Test No. | | | |
|---|---|---|---|---|---|
| | | Comparative | Comparative | Comparative | Comparative |
| | | Example 7. | Example 8. | Example 9. | Example 10. |
| Properties | Coating | Al-3 | Al-7 | Al-3 | Al-3 |
| of impact- | solution No. | | | | |
| resistant | of impact- | | | | |
| layer | resistant layer | | | | |
| | Disperse phase | nanoSiO2/50 | nanoSiO2/50 | nanoSiO2/50 | nanoSiO2/50 |
| | (type/content(wt %)) | | | | |
| | Continuous phase | TMPTA15EO/ | TMPTA15EO/ | TMPTA15EO/ | TMPTA15EO/ |
| | (composition/ | DPHA = 8/2 | DPHA = 8/2 | DPHA = 8/2 | DPHA = 8/2 |
| | content) | | | | |
| | Modulus ratio | 70/1 = 70 | 70/1 = 70 | 70/1 = 70 | 70/1 = 70 |
| | of “disperse | | | | |
| | phase/continuous | | | | |
| | phase” | | | | |
| | Modulus of | 1.5 | 1.5 | 1.5 | 1.5 |
| | impact-resistant | | | | |
| | layer (GPa) | | | | |
| | Thickness of | 5.0 | 5.0 | 5.0 | 5.0 |
| | impact-resistant | | | | |
| | layer (μm) | | | | |
| Cover | Cover materials | AF/TPU/ | AF/Mpior/ | AF/Mpior/ | AF/Mpior/ |
| | (and structure) | AD/UTG/IR | AD/UTG/IR | AD/UTG/IR | OCA/UTG/IR |
| | Thickness of | 3/50/15/ | 3/80/15/ | 3/13/20/ | 3/13/15/ |
| | cover (each | 30/5 | 30/5 | 30/5 | 30/5 |
| | layer in the | | | | |
| | structure) (μm) | | | | |
| | Modulus of | 0.01 | 3.8 | 3.8 | 3.8 |
| | plastic | | | | |
| | film (GPa) | | | | |
| | Modulus of | 0.23 | 0.23 | 0.23 | 2 × 10⁻⁵ |
| | adhesive | | | | |
| | layer (GPa) | | | | |
| | Total thickness | 66.00 | 133.00 | 71.00 | 76.00 |
| | (μm) | | | | |
| Test | Haze | 0.70 | 0.70 | 0.57 | 0.57 |
| results | Roughness | <10 nm | <10 nm | <10 nm | <10 nm |
| of cover | (impact-resistant | | | | |
| | layer surface) | | | | |
| | Pen drop height | 0.5 | 9 | 6 | 1.5 |
| | (UTG breakage) | | | | |
| | Ball drop height | 1.5 | 60 | 55 | 5 |
| | (UTG breakage) | | | | |
| | Bending | (Inner fold | (Inner fold | (Inner fold | (Inner fold |
| | resistance | R3 × 200,000 | R3 × 200,000 | R3 × 200,000 | R3 × 200,000 |
| | | times) | times) | times) | times) |
| | | ◯ | X | ◯ | ◯ |
| | | (Outer fold | (Outer fold | (Outer fold | (Outer fold |
| | | R4 × 200,000 | R4 × 200,000 | R4 × 200,000 | R4 × 200,000 |
| | | times) | times) | times) | times) |
| | | ◯ | X | ◯ | ◯ |
| | Steel wool scratch | X | ◯ | X | X |
| | (Reciprocating | | | | |
| | 2,500 times) | | | | |

<Note>
1. Mpior film is a transparent polyimide film made by Microcosm Technology CO., LTD..
2. TMPTA15EO refers to 15EO-TMPTA.
3. The unit of pen drop height and ball drop height is centimeter.

As shown in Table 1, the flexible display cover substrate of Comparative Example 1 has a 2 cm-pen drop height and a 4 cm-ball drop height because it has no impact-resistant layer. That is, the flexible display cover substrate of Comparative Example 1 can only withstand a 2 cm-pen drop strength and a 4 cm-ball drop strength, which is significantly inferior to the flexible display cover substrate of Examples 1-5.

The results in Table 1 also show that the flexible display cover substrate of Comparative Example 3 has poor pen drop strength and ball drop strength because the elastic modulus ratio of the disperse phase to the continuous phase is 2. The flexible display cover substrate of Comparative Example 10 also has poor pen drop strength and ball drop strength because the elastic modulus of the adhesive layer is too small.

From the results in Table 1, it can be seen that the flexible display cover substrate of the present invention has a bending resistance that can withstand an inner fold of R=3 mm for 200,000 folds and an outer fold of R=4 mm for 200,000 folds, and a scratch resistance that can withstand steel wool scratching for 2,500 reciprocating times.

As can be seen from the above, according to the present invention, a flexible display cover substrate having the following characteristics can be obtained: (1) low haze; (2) low roughness; (3) good pen drop resistance; (4) good ball drop resistance; (5) good bending resistance; (6) good scratch resistance.

The above proposes only preferred embodiments of the present invention and is not intended to limit the present invention. It should be indicated that for ordinary technicians in this technical field, several improvements and modifications can be made without departing from the technical principles of the present invention, and these improvements and modifications should also be regarded as the protection scope of the present invention.

What is claimed is:

1. A flexible display cover substrate, comprising:
an ultra-thin glass;
a plastic film disposed on the ultra-thin glass;
an anti-fouling layer disposed on the plastic film;
an impact-resistant layer disposed on at least one surface of the ultra-thin glass or the plastic film, wherein the impact-resistant layer comprises a disperse phase and a continuous phase, a percentage of the disperse phase in the impact-resistant layer is 10-50 wt %, an elastic modulus ratio of the disperse phase to the continuous phase is greater than or equal to 70, and an elastic modulus of the impact-resistant layer is greater than or equal to 1 GPa; and
an adhesive layer disposed between the ultra-thin glass and the plastic film, wherein an elastic modulus of the adhesive layer is greater than or equal to 0.1 GPa.

2. The flexible display cover substrate of claim 1, wherein an elastic modulus of the plastic film is greater than or equal to 3 GPa.

3. The flexible display cover substrate of claim 1, wherein the impact-resistant layer is disposed at a lower surface of the ultra-thin glass and opposite to the plastic film.

4. The flexible display cover substrate of claim 3, wherein the adhesive layer serves as a first adhesive layer, the flexible display cover substrate further comprises a second adhesive layer, and the impact-resistant layer is adhered to the lower surface of the ultra-thin glass through the second adhesive layer.

5. The flexible display cover substrate of claim 1, wherein the impact-resistant layer is disposed between the anti-fouling layer and the plastic film.

6. The flexible display cover substrate of claim 1, wherein the impact-resistant layer is disposed at a lower surface of the plastic film, and the impact-resistant layer is adhered to the ultra-thin glass through the adhesive layer.

7. The flexible display cover substrate of claim 1, wherein the impact-resistant layer is formed of an impact-resistant composition, which comprises a multifunctional (meth)acrylate compound, an initiator and nanoparticles.

8. The flexible display cover substrate of claim 1, wherein a water drop angle of the anti-fouling layer is greater than or equal to 100 degrees.

9. The flexible display cover substrate of claim 1, wherein the anti-fouling layer is formed of an anti-fouling composition, which comprises a hydrophobic photocurable resin, an antistatic agent, a compound having three or more reactive functional groups, an elastic oligomer, an initiator, and modified inorganic nano-particles, and a weight ratio of the compound having three or more reactive functional groups to the elastic oligomer ranges from 0.25 to 3.

10. The flexible display cover substrate of claim 1, wherein a thickness of the plastic film is less than or equal to 50 microns.

11. The flexible display cover substrate of claim 1, wherein a thickness of the adhesive layer is less than or equal to 15 microns.

12. The flexible display cover substrate of claim 1, being able to withstand a pen drop strength of greater than or equal to 5 cm.

13. The flexible display cover substrate of claim 1, being able to withstand a ball drop strength of greater than or equal to 50 cm.

14. The flexible display cover substrate of claim 1, having a thickness of less than or equal to 110 μm.

15. The flexible display cover substrate of claim 1, having a folding resistance that can withstand an inner folding of R=3 mm for 200,000 times, wherein R is a bending radius.

16. The flexible display cover substrate of claim 1, having a scratch resistance that can withstand steel wool scratching for 2,500 reciprocating times.
